(19) United States
(12) Patent Application Publication
(10) Pub. No.: US 2026/0136539 A1
(43) Pub. Date: May 14, 2026

(54) THREE DIMENSIONAL SEMICONDUCTOR DEVICE AND METHOD OF MANUFACTURING THE SAME

(71) Applicant: SAMSUNG ELECTRONICS CO., LTD., Suwon-si (KR)

(72) Inventors: Yujin KIM, Suwon-si (KR); Woochul KIM, Suwon-si (KR); Hyebin KIM, Suwon-si (KR); Gyuhwan OH, Suwon-si (KR); Eunsuk JANG, Suwon-si (KR); Jihoon CHOI, Suwon-si (KR)

(73) Assignee: SAMSUNG ELECTRONICS CO., LTD., Suwon-si (KR)

(21) Appl. No.: 19/259,789

(22) Filed: Jul. 3, 2025

(30) Foreign Application Priority Data
Nov. 12, 2024 (KR) 10-2024-0160464

(51) Int. Cl. H10B 12/00

(52) U.S. Cl. CPC H10B 12/482; H10B 12/02

(57) ABSTRACT

A three dimensional semiconductor device may include semiconductor patterns on a substrate, extending in a first direction parallel to a lower surface of the substrate, spaced apart from each other in a vertical direction perpendicular to the lower surface of the substrate, word lines respectively surrounding the semiconductor patterns, each extending in a second direction parallel to the lower surface of the substrate and orthogonal to the first direction, a lower insulating layer adjacent to ends of a first group of the semiconductor patterns, a bit line disposed on the lower insulating layer and adjacent to ends of a second group of the semiconductor patterns, and a separation insulating pattern penetrating at least a portion of the lower insulating layer. The separation insulating pattern may have a shape tapered toward the substrate.

### CROSS-REFERENCE TO RELATED APPLICATIONS

This U.S. non-provisional patent application claims priority under 35 U.S.C. § 119 to Korean Patent Application No. 10-2024-0160464 filed on Nov. 12, 2024, in the Korean Intellectual Property Office, the entire contents of which are hereby incorporated by reference.

### BACKGROUND OF THE INVENTION

The inventive concept relates to a three dimensional semiconductor device and a method of manufacturing the same, and more specifically, relates to a three dimensional semiconductor device with improved reliability and integration.

Semiconductor devices are widely used in the electronics industry because of their small sizes, multi-functional characteristics, and/or low manufacturing costs. Semiconductor devices may be categorized as one of semiconductor memory devices for storing logical data, semiconductor logic devices for processing logical data, and hybrid semiconductor devices having both the function of the semiconductor memory devices and the function of the semiconductor logic devices.

As high-speed and/or low-power electronic devices have been in demand, high-speed and/or low-voltage semiconductor devices used therein have also been in demand, and highly integrated semiconductor devices have been required to satisfy these demands. However, as the integration densities of semiconductor devices increase, electrical characteristics and production yields of the semiconductor devices may be reduced. Thus, techniques for improving electrical characteristics and production yields of semiconductor devices have been variously studied.

### SUMMARY

An object of the inventive concept is to provide a three dimensional semiconductor device with improved electrical characteristics and reliability.

The problem to be solved by the inventive concept is not limited to the problems mentioned above, and other problems not mentioned may be clearly understood by those skilled in the art from the description below.

A three dimensional semiconductor device according to some embodiments of the inventive concept may include semiconductor patterns disposed on a substrate, extending in a first direction parallel to a lower surface of the substrate, spaced apart from each other in a vertical direction perpendicular to the lower surface of the substrate, word lines respectively surrounding the semiconductor patterns, extending in a second direction parallel to the lower surface of the substrate and orthogonal to the first direction, a lower insulating layer disposed adjacent to ends of a first group of the semiconductor patterns, a bit line disposed on the lower insulating layer and adjacent to ends of a second other group of the semiconductor patterns, and a separation insulating pattern penetrating at least a portion of the lower insulating layer. The separation insulating pattern may have a shape tapered toward the substrate.

A three dimensional semiconductor device according to some embodiments of the inventive concept may include semiconductor patterns disposed on a substrate, extending in a first direction parallel to a lower surface of the substrate, spaced apart from each other in a vertical direction perpendicular to the lower surface of the substrate, word lines respectively surrounding the semiconductor patterns, extending in a second direction parallel to the lower surface of the substrate and orthogonal to the first direction, a lower insulating layer disposed adjacent to end portions of a first group the semiconductor patterns, a bit line disposed on the lower insulating layer and adjacent to end portions of a second group of the semiconductor patterns, and a separation insulating pattern penetrating at least a portion of the lower insulating layer. An uppermost surface of the separation insulating pattern is disposed at a higher level than a recessed surface of the lower insulating layer.

A three dimensional semiconductor device according to some embodiments of the inventive concept may include semiconductor patterns disposed on a substrate, extending in a first direction parallel to a lower surface of the substrate, spaced apart from each other in a vertical direction perpendicular to the lower surface of the substrate, each of the semiconductor patterns having a first end and a second end opposing each other in the first direction, word lines respectively surrounding the semiconductor patterns, extending in a second direction parallel to the lower surface of the substrate and orthogonal to the first direction, gate insulating patterns disposed between the semiconductor patterns and the word lines, respectively, data storage patterns connected to the first ends of the semiconductor patterns, extending in the vertical direction, a lower insulating layer disposed adjacent to the second ends of a first group of the semiconductor patterns, a bit line disposed on the lower insulating layer, adjacent to the second ends of a second group of the semiconductor patterns, and a separation insulating pattern penetrating at least a portion of the lower insulating layer. A width of the separation insulating pattern in the first direction continuously changes in the vertical direction.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic circuit diagram illustrating a three dimensional semiconductor device according to some embodiments of the inventive concept.

FIGS. 2A, 2B, and 2C are schematic perspective views of a three dimensional semiconductor device according to some embodiments of the inventive concept.

FIG. 3 is a perspective view illustrating semiconductor patterns, word lines, bit lines, and data storage patterns of a three dimensional semiconductor device according to some embodiments of the inventive concept.

FIG. 4 is a plan view of a three dimensional semiconductor device according to some embodiments of the inventive concept.

FIG. 5A is a cross-sectional view of a three dimensional semiconductor device according to some embodiments of the inventive concept, corresponding to line A-A′ of FIG. 4.

FIG. 5B is a cross-sectional view of a three dimensional semiconductor device according to some embodiments of the inventive concept, corresponding to line B-B′ of FIG. 4.

FIGS. 6A and 6B are enlarged views corresponding to portion ‘P’ of FIG. 5A.

FIG. 7 is an enlarged view corresponding to portion ‘Q’ of FIG. 5A.

FIGS. 8, 9A, 9B, 9C, 10, 11, 12, 13, 14, 15, 16, 17 and 18 are views illustrating a method of manufacturing a three dimensional semiconductor device according to some embodiments of the inventive concept.

FIGS. 19, 20 and 21 are cross-sectional views of a three dimensional semiconductor device according to some embodiments of the inventive concept.

### DETAILED DESCRIPTION

Hereinafter, to explain the inventive concept in detail, embodiments according to the inventive concept will be described with reference to the attached drawings.

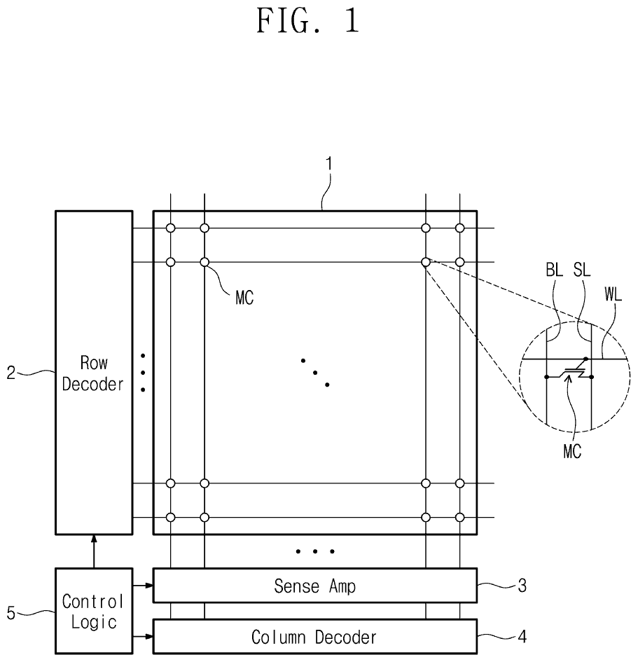

FIG. 1 is a schematic circuit diagram illustrating a three dimensional semiconductor device according to some embodiments of the inventive concept.

Referring to FIG. 1, a three dimensional semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally disposed, and each memory cell MC may be connected to one of the word lines WL, one of the bit lines BL, and one of the source lines SL. In some embodiments, each of the memory cells MC may include one transistor including a memory layer (or a data storage layer).

The row decoder 2 may be configured to decode address information, which is input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of control circuits.

The sense amplifier 3 may be configured to sense, amplify, and output a difference in voltage between one of the bit lines BL, which is selected based on address information decoded by the column decoder 4, and a reference bit line.

The column decoder 4 may provide a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

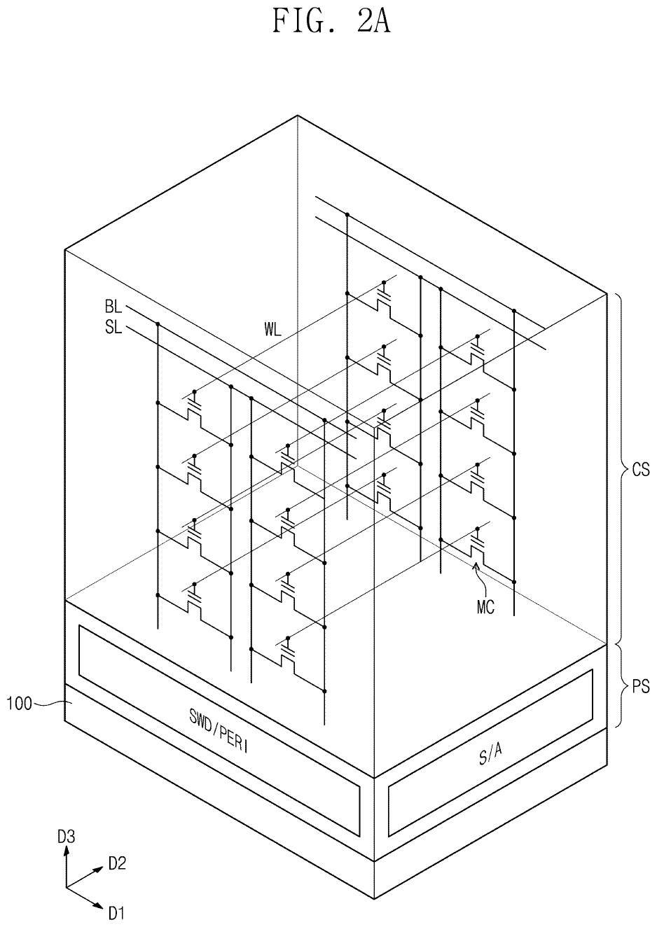

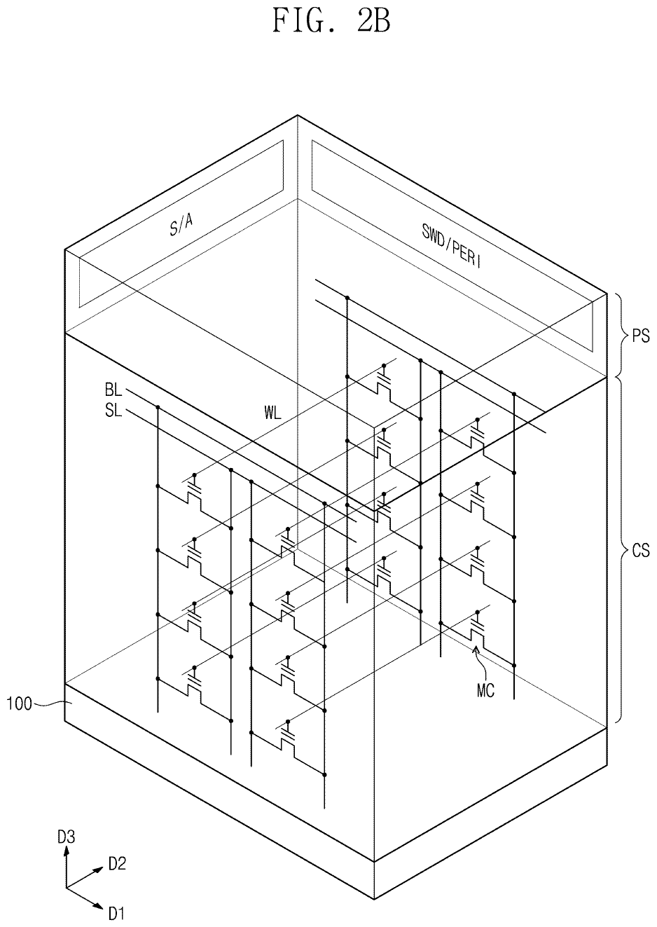

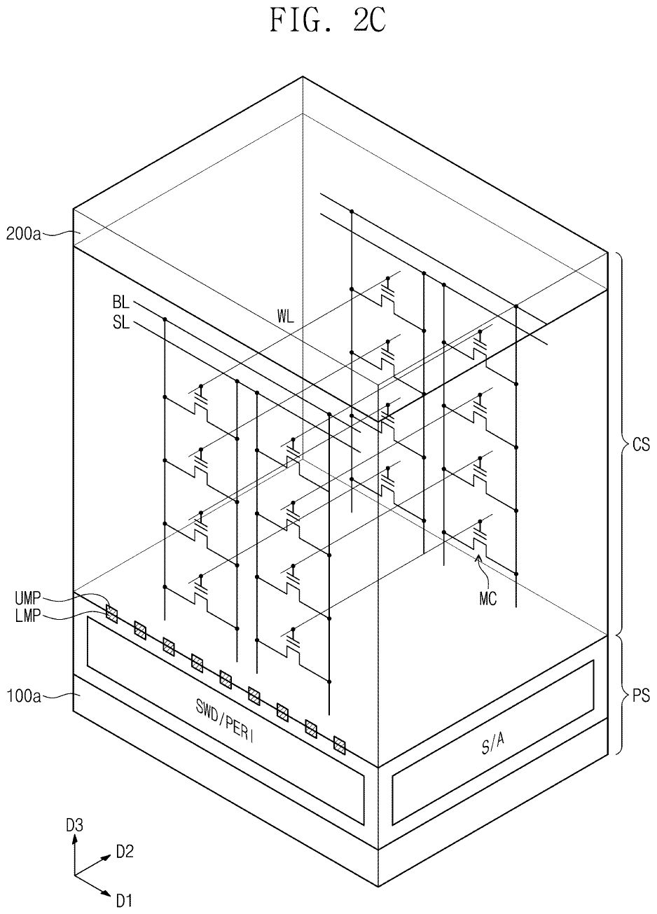

FIGS. 2A, 2B, and 2C are schematic perspective views of a three dimensional semiconductor device according to some embodiments of the inventive concept.

Referring to FIG. 2A, a three dimensional semiconductor device may include a substrate 100, a peripheral circuit structure PS on the substrate 100, and a cell array structure CS on the peripheral circuit structure PS.

The peripheral circuit structure PS may include core and peripheral circuits formed on the substrate 100. The core and peripheral circuits may include the row and column decoders 2 and 4 (e.g., FIG. 1), the sense amplifier 3 (e.g., FIG. 1), and the control logic 5 (e.g., FIG. 1) described with reference to FIG. 1.

The substrate 100 may have a plate shape extending along a plane defined by a first direction D1 and a second direction D2. The first direction D1 and the second direction D2 may be parallel to a lower surface of the substrate 100 and may intersect each other. For example, the first direction D1 and the second direction D2 may be horizontal directions that are orthogonal to each other. The peripheral circuit structure PS and the cell array structure CS may be sequentially stacked on the substrate 100 in a vertical direction D3 that is perpendicular to the lower surface of the substrate 100.

The cell array structure CS may include bit lines BL, source lines SL, and word lines WL, and memory cells MC therebetween. Each of the memory cells MC may be connected to one word line WL, one bit line BL, and one source line SL.

Referring to FIG. 2B, a semiconductor device may include a cell array structure CS on a substrate 100 and a peripheral circuit structure PS on the cell array structure CS. The cell array structure CS may be disposed between the substrate 100 and the peripheral circuit structure PS. The peripheral circuit structure PS may include core and peripheral circuits.

Referring to FIG. 2C, a semiconductor device may have a chip to chip (C2C) structure. The peripheral circuit structure PS may include a first substrate 100a. Lower metal pads LMP may be provided at the uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and upper metal pads UMP may be provided at the lowermost portion of the cell array structure CS. The upper metal pads UMP may be electrically connected to bit lines BL, source lines SL, and word lines WL. The upper metal pads UMP may be electrically connected to memory cells MC.

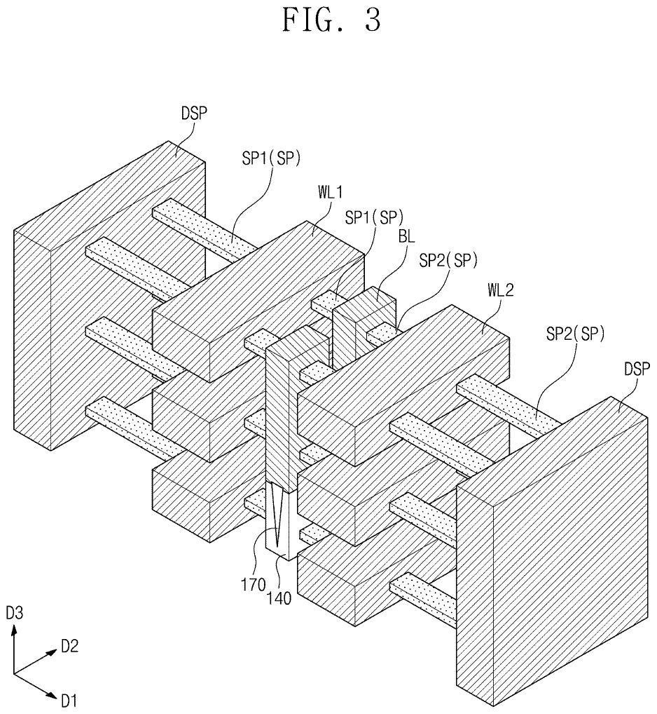

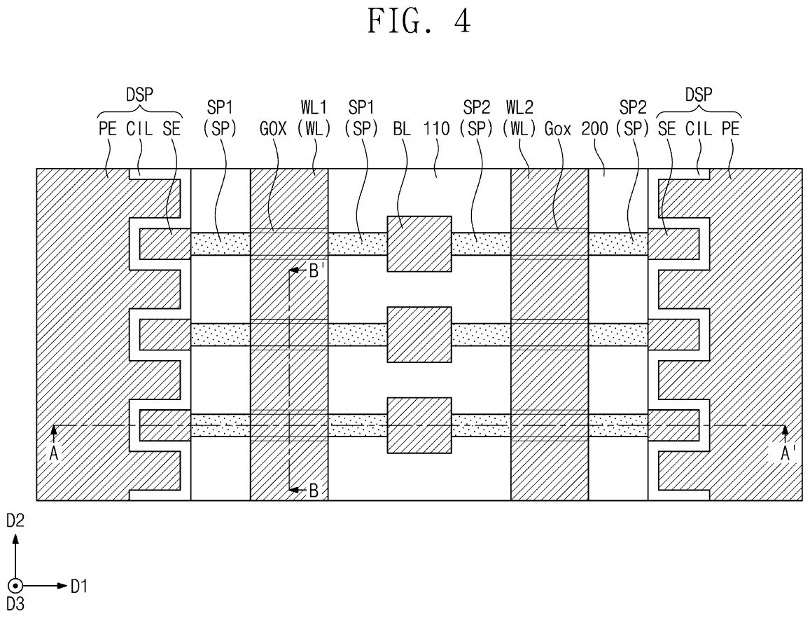

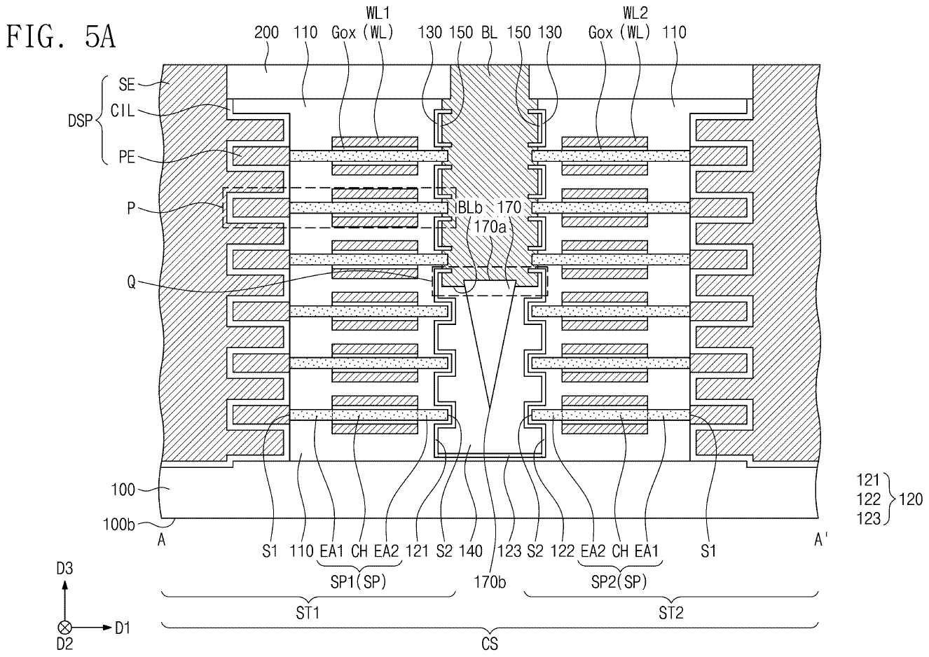

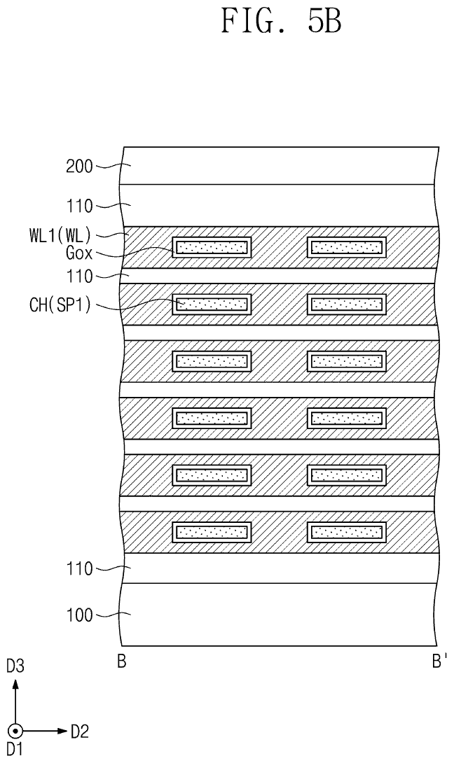

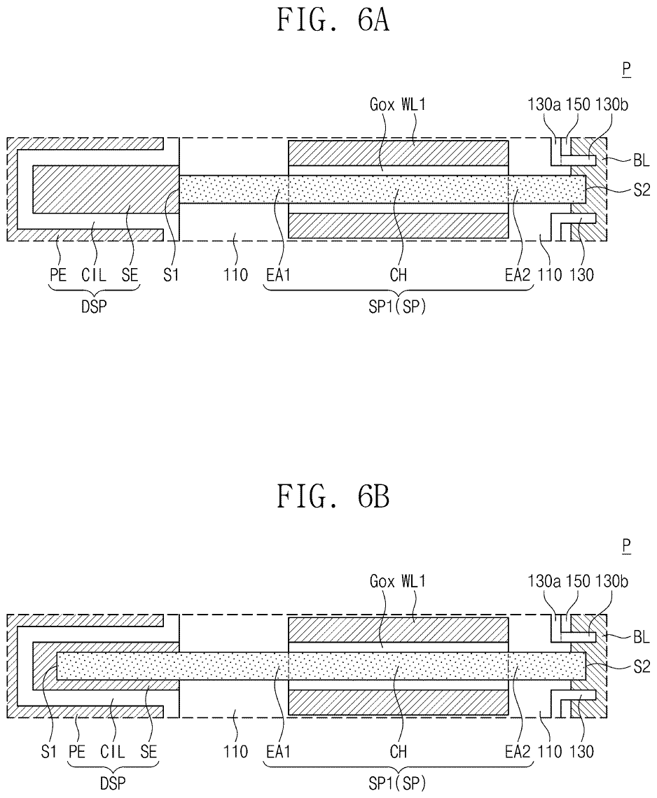

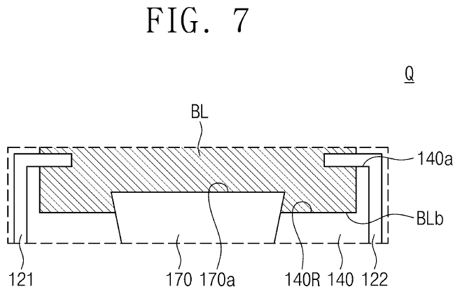

FIG. 3 is a perspective view illustrating semiconductor patterns, word lines, bit lines, and data storage patterns of a three dimensional semiconductor device according to some embodiments of the inventive concept. FIG. 4 is a plan view of a three dimensional semiconductor device according to some embodiments of the inventive concept. FIG. 5A is a cross-sectional view of a three dimensional semiconductor device according to some embodiments of the inventive concept, corresponding to line A-A′ of FIG. 4. FIG. 5B is a cross-sectional view of a three dimensional semiconductor device according to some embodiments of the inventive concept, corresponding to line B-B′ of FIG. 4. FIGS. 6A and 6B are enlarged views corresponding to portion ‘P’ of FIG. 5A. FIG. 7 is an enlarged view corresponding to portion ‘Q’ of FIG. 5A.

Referring to FIGS. 3 to 7, a three dimensional semiconductor device may include a substrate 100. For example, the substrate 100 may be a semiconductor substrate, an insulator substrate, a silicon-on-insulator (SOI) substrate, or a germanium-on-insulator (GOI) substrate. The semiconductor substrate may be, for example, a silicon substrate, a germanium substrate, or a silicon-germanium substrate. The substrate 100 may have a plate shape extending along a plane defined by a first direction D1 and a second direction D2. In the present specification, the first direction D1 and the second direction D2 may be directions that are parallel to and intersect a lower surface 100b of the substrate 100. A third direction D3 may be a vertical direction D3 that is perpendicular to the lower surface 100b of the substrate 100. The first to third directions D1, D2, and D3 may be directions that are orthogonal to each other.

A cell array structure CS may be provided on the substrate 100. The cell array structure CS may include a first stacked structure ST1 and a second stacked structure ST2 spaced apart from each other in the first direction D1, and a lower insulating layer 140 and a bit lines BL interposed therebetween. For example, although not shown in the drawing, the cell array structure CS may include a plurality of cell array structures CS spaced apart from each other in the first direction D1. Hereinafter, for convenience of explanation, a single cell array structure CS will be described, but the following description may be equally applied to other cell array structures CS.

Each of the first stacked structure ST1 and the second stacked structure ST2 may include semiconductor patterns SP, word lines WL, a data storage pattern DSP, gate insulating patterns Gox, and a buried insulating pattern 110. For example, the first and second stacked structures ST1 and ST2 may be mirror-symmetrical with respect to a lower insulating layer 140 and a bit line BL. The semiconductor patterns SP and word lines WL of the first stacked structure ST1 may be referred to as first semiconductor patterns SP1 and first word lines WL1, respectively. The semiconductor patterns SP and word lines WL of the second stacked structure ST2 may be referred to as second semiconductor patterns SP2 and second word lines WL2, respectively. Hereinafter, for convenience of explanation, a single first stacked structure ST1 is described, but the following explanation may be equally applied to a second stacked structure ST2 spaced apart in the first direction D1.

A first semiconductor pattern SP1 may extend in the first direction D1 on the substrate 100. The first semiconductor pattern SP1 may be spaced apart from the substrate 100. In other words, the first semiconductor pattern SP1 may be floated from the substrate 100. A plurality of first semiconductor patterns SP1 may be provided. The first semiconductor patterns SP1 may be spaced apart from each other in the second direction D2 and a vertical direction D3. The first semiconductor patterns SP1 spaced apart from each other in the vertical direction D3 may vertically overlap each other when viewed in a plan view. Sidewalls of the first semiconductor patterns SP1 spaced apart from each other in the vertical direction D3 may be aligned with each other in the vertical direction D3.

Each of the first semiconductor patterns SP1 may have end portions EA1 and EA2 spaced apart from each other in a first direction D1. For example, each of the first semiconductor patterns SP1 may include a first edge portion EA1 and a second edge portion EA2 spaced apart from each other in the first direction D1, and a channel region CH interposed therebetween. The first edge portion EA1 and the second edge portion EA2 may also be referred to as a first end portion EA1 and a second end portion EA2, respectively. The channel region CH of each of the first semiconductor patterns SP1 may be surrounded by a first word line WL1. The first edge portion EA1 of each of the first semiconductor patterns SP1 may be adjacent to a data storage pattern DSP. The first edge portion EA1 may be electrically connected to the data storage pattern DSP. The second edge portions EA2 of a first group of the first semiconductor patterns SP1 may be adjacent to the lower insulating layer 140. The second edge portions EA2 of a second group of the first semiconductor patterns SP1 may be adjacent to the bit line BL. The second edge portions EA2 of the first group of the first semiconductor patterns SP1 may not be electrically connected to the bit line BL. The second edge portions EA2 of the second group of the first semiconductor patterns SP1 may be electrically connected to the bit line BL.

Each of the first semiconductor patterns SP1 may have a first side surface S1 and a second side surface S2 facing each other in the first direction D1. The first side surface S1 may be a side surface of the first edge portion EA1, and the second side surface S2 may be a side surface of the second edge portion EA2. The first surface side S1 of each of the first semiconductor patterns SP1 may be adjacent to the data storage pattern DSP. The second surface side S2 of the first group of the first semiconductor patterns SP1 may be adjacent to the lower insulating layer 140. The second surface side S2 of the second group of the first semiconductor patterns SP1 may be adjacent to the bit line BL.

The first semiconductor pattern SP1 provided in the first stacked structure ST1 may be spaced apart from the second semiconductor pattern SP2 provided in the second stacked structure ST2 in the first direction D1. The first edge portion EA1, the channel region CH, and the second edge portion EA2 of the first semiconductor pattern SP1 may be sequentially disposed in the first direction D1. The first edge portion EA1, the channel region CH, and the second edge portion EA2 of the second semiconductor pattern SP2 may be sequentially disposed in a direction opposite to the first direction D1.

The first and second semiconductor patterns SP1 and SP2 may include at least one of a single crystal semiconductor, a polycrystalline semiconductor, an oxide semiconductor, or a two dimensional material. For example, the single crystal semiconductor may be single crystal silicon. For example, the polycrystalline semiconductor may be polysilicon. For example, the oxide semiconductor may be indium gallium zinc oxide (IGZO). For example, the two dimensional material may be MoS2, WS2, MoSe2, or WSe2.

For example, each of the first and second edge portions EA1 and EA2 of the first and second semiconductor patterns SP1 and SP2 may include an impurity region doped with an impurity (e.g., an n-type or p-type impurity) therein. The impurity region may constitute a source/drain region of the transistor.

The first word line WL1 may surround the channel region CH of the first semiconductor pattern SP1 and may extend in the second direction D2. For example, the first word line WL1 may have a structure that completely surrounds the channel region CH of the first semiconductor pattern SP1 (i.e., a gate all around structure). One first word line WL1 may surround the channel region CH of each of the first semiconductor patterns SP1 spaced apart from each other in the second direction D2. A plurality of first word lines WL1 may be provided. Each of the first word lines WL1 may surround a channel region CH of a corresponding first semiconductor pattern SP1 among the first semiconductor patterns SP1 spaced apart from each other in the vertical direction D3 and may extend in the second direction D2. The first word lines WL1 may be spaced apart from each other in the vertical direction D3.

The first word line WL1 provided in the first stacked structure ST1 may be spaced apart from the second word line WL2 provided in the second stacked structure ST2 in the first direction D1.

The first and second word lines WL1 and WL2 may include at least one of, for example, but not limited to, doped polysilicon, a metal (e.g., Al, Cu, Ti, Ta, Ru, W, Mo, Pt, Ni, Co), a conductive metal nitride (e.g., TiN, TaN, WN, NbN, TiAIN, TiSiN, TaSiN, RuTiN), a conductive metal silicide or a conductive metal oxide (e.g., PtO, RuO₂, IrO₂, SrRuO₃ (SRO), (Ba,Sr) RuO₃ (BSRO), CaRuO₃ (CRO), LSCo). The word line WL may include a single layer or multiple layers of the above-mentioned materials. In some embodiments, the word line WL may include a two dimensional semiconductor material, for example, the two dimensional material may include graphene, carbon nanotubes, or a combination thereof.

The gate insulating pattern Gox may be interposed between the first word line WL1 and the first semiconductor pattern SP1. The gate insulating pattern Gox may surround the first semiconductor pattern SP1. The first word line WL1 may surround the channel region CH of the first semiconductor pattern SP1 on the gate insulating pattern Gox. A plurality of gate insulating patterns Gox may be provided. Each of the gate insulating patterns Gox may surround a corresponding first semiconductor pattern SP1.

The gate insulating pattern Gox may include at least one of silicon oxide, silicon oxynitride, or a high-k dielectric material having a higher dielectric constant than that of silicon oxide. The high-k dielectric material may include a metal oxide or a metal oxynitride. For example, a high-k dielectric material usable as a gate insulating pattern Gox may include at least one of HfO₂, HfSiO, HfSiON, HfTaO, HfTIO, HfZrO, ZrO₂, or Al₂O₃, but is not limited thereto. A material having a high-k dielectric is defined as a material having a higher dielectric constant than that of silicon oxide.

The buried insulating pattern 110 may be provided on the substrate 100 and in the first stacked structure ST1. The buried insulating pattern 110 may be interposed between the data storage pattern DSP and the first word line WL1, between the first semiconductor patterns SP1 adjacent to each other in the vertical direction D3, between the first semiconductor patterns SP1 adjacent to each other in the second direction D2, and between the first word lines WL1 adjacent to each other in the vertical direction D3. The buried insulating pattern 110 may cover the first edge portion EA1 and the second edge portion EA2 of the first semiconductor pattern SP1. The buried insulating pattern 110 may include a single layer or a composite layer including an insulating material. The buried insulating pattern 110 may also be provided in the second stacked structure ST2. The lower portions of the buried insulating pattern 110 in the first stacked structure ST1 and the buried insulating pattern 110 in the second stacked structure ST2 may protrude toward each other and may be connected.

The data storage pattern DSP may be provided on the first surface side S1 of each of the first semiconductor patterns SP1. The data storage pattern DSP may extend in the vertical direction D3. Accordingly, the data storage pattern DSP may be in contact with the first side surface S1 of each of the first semiconductor patterns SP1 spaced apart from each other in the vertical direction D3, and may be electrically connected to the first semiconductor patterns SP1.

The data storage pattern DSP may include a storage electrode SE, a plate electrode PE, and a capacitor dielectric layer CIL interposed therebetween. As an example, the three dimensional semiconductor device may be a dynamic random access memory (DRAM), and in this case, the data storage pattern DSP may be utilized as a capacitor. The storage electrode SE may be spaced apart from the plate electrode PE with the capacitor dielectric layer CIL interposed therebetween.

Each of the storage electrode SE and the plate electrode PE may include a conductive material. For example, each of the storage electrode SE and the plate electrode PE may include at least one of impurity-doped silicon (Si), impurity-doped silicon germanium (SiGe), a metal material (e.g., Ti, Mo, W, Cu, Al, Ta, Ru, Ir, Co, Pt, Au, Ag, etc.), a metal nitride (e.g., nitrides including Ti, Mo, W, Cu, Al, Ta, Ru, Ir, Co, Pt, Au, Ag, titanium silicon nitride (e.g., TiSiN), titanium aluminum nitride (e.g., TiAIN), tantalum aluminum nitride (e.g., TaAIN)), a conductive oxide (e.g., PtO, RuO₂, IrO₂, SrRuO₃ (SRO), (Ba,Sr) RuO₃ (BSRO), CaRuO₃ (CRO), LSCo), or a metal silicide. Each of the storage electrode SE and the plate electrode PE may be a single layer made of a single material or a composite layer including two or more materials.

For example, the capacitor dielectric layer CIL may include at least one of a metal oxide such as HfO₂, ZrO₂, Al₂O₃, La₂O₃, Ta₂O₃, and TiO₂, and a dielectric material having a perovskite structure such as SrTiO₃ (STO), (Ba,Sr) TiO₃ (BST), BaTiO₃, PZT, and PLZT.

For another example, the data storage pattern DSP may be a variable resistance pattern that may be switched between two resistance states by an electrical pulse. In this case, the data storage pattern DSP may include a phase-change material, perovskite compounds, a transition metal oxide, magnetic materials, ferromagnetic materials, or antiferromagnetic materials whose crystal state changes depending on the amount of current.

The storage electrode SE may extend in a direction opposite to the first direction D1 on the first surface side S1 of the first semiconductor pattern SP1. Although not shown, a silicide pattern (not shown) may be provided between the storage electrode SE and the first semiconductor pattern SP1. The silicide pattern may include a metal silicide (e.g., a silicide including Ti, Mo, W, Cu, Al, Ta, Ru, Ir, or Co). A plurality of storage electrodes SE may be provided, and the storage electrodes SE may be spaced apart from each other in the vertical direction D3.

The plate electrode PE may include a first portion extending in the vertical direction D3 and a second portion protruding from the first portion in the first direction D1. The second portion of the plate electrode PE may be interposed between storage electrodes SE spaced apart in the vertical direction D3.

The lower insulating layer 140 may be provided between the first stacked structure ST1 and the second stacked structure ST2 spaced apart from each other in the first direction D1. The lower insulating layer 140 may extend in the vertical direction D3. A portion of the buried insulating pattern 110 may be interposed between the lower insulating layer 140 and the substrate 100. Specifically, lower portions of the buried insulating pattern 110 of the first stacked structure ST1 and the buried insulating pattern 110 of the second stacked structure ST2 may extend toward each other. Accordingly, the lower insulating layer 140 may be spaced apart from the substrate 100 with the extended portions of the buried insulating patterns 110 of the first and second stacked structures ST1 and ST2 interposed therebetween.

The lower insulating layer 140 may be interposed between a first group of the first semiconductor patterns SP1 and a first group of the second semiconductor patterns SP2. The lower insulating layer 140 may be horizontally overlapped (e.g., in the first direction D1) with the first group of the first semiconductor patterns SP1 and the first group of the second semiconductor patterns SP2. The lower insulating layer 140 may be spaced apart from the the first group of the first semiconductor patterns SP1 and the first group of the second semiconductor patterns SP2 with the buried insulating pattern 110 interposed therebetween. Specifically, the lower insulating layer 140 may be disposed adjacent to the first and second semiconductor patterns SP1 and SP2 that are relatively lower positioned among the first and second semiconductor patterns SP1 and SP2 spaced apart from each other in the vertical direction D3. Accordingly, the lowermost first semiconductor pattern SP1 and the second semiconductor pattern SP2 among the first and second semiconductor patterns SP1 and SP2 may be disposed adjacent to the lower insulating layer 140.

The lower insulating layer 140 may include an insulating material, and may include, for example, at least one of silicon oxide, silicon nitride, silicon oxynitride, or a low-k dielectric material.

A line layer 120 may be interposed between the lower insulating layer 140 and the buried insulating pattern 110. The line layer 120 may include a first line layer 121 adjacent to the first stacked structure ST1, a second line layer 122 adjacent to the second stacked structure ST2, and a horizontal line layer 123 connecting the first and second line layers 121 and 122. The lower insulating layer 140 may be spaced apart from the buried insulating pattern 110 with the line layer 120 interposed therebetween. The line layer 120 may include an insulating material, and may include, for example, at least one of silicon oxide, silicon nitride, silicon oxynitride, or a low-k dielectric material.

The bit line BL may be provided on the lower insulating layer 140. The bit line BL may be disposed between the first stacked structure ST1 and the second stacked structure ST2 spaced apart from each other in the first direction D1. The bit line BL may extend in the vertical direction D3. The bit line BL may be interposed between a second group of the first semiconductor patterns SP1 and a second group of the second semiconductor patterns SP2. The bit line BL may overlap the second group of the first semiconductor patterns SP1 and the second group of the second semiconductor groups SP2 horizontally (e.g., in the first direction D1). The bit line BL may be connected to the second group of the first semiconductor patterns SP1 and the second group of the second semiconductor groups SP2. Specifically, the bit line BL may be disposed adjacent to the first and second semiconductor patterns SP1 and SP2 that are positioned at a relatively higher level among the first and second semiconductor patterns SP1 and SP2 spaced apart from each other in the vertical direction D3. Accordingly, the uppermost first semiconductor pattern SP1 and the second semiconductor pattern SP2 among the first and second semiconductor patterns SP1 and SP2 may be disposed adjacent to the bit line BL.

A plurality of bit lines BL may be provided. The bit lines BL may be spaced apart from each other along the second direction D2.

The bit line BL may include, for example, at least one of doped polysilicon, a metal (e.g., Al, Cu, Ti, Ta, Ru, W, Mo, Pt, Ni, Co), a conductive metal nitride (e.g., TIN, TaN, WN, NbN, TiAIN, TiSiN, TaSiN, RuTiN), a conductive metal silicide or a conductive metal oxide (e.g., PtO, RuO₂, IrO₂, SrRuO₃ (SRO), (Ba,Sr) RuO₃ (BSRO), CaRuO₃ (CRO), LSCo), but is not limited thereto. The bit line BL may include a single layer or multiple layers of the aforementioned materials. In some embodiments, the bit line BL may include a two dimensional semiconductor material, and for example, the two dimensional material may include graphene, carbon nanotube, or a combination thereof.

A line pattern 130 may be provided between the first semiconductor patterns SP1 adjacent to the bit line BL among the first semiconductor patterns SP1. Specifically, the line pattern 130 may be adjacent to the bit line BL and may be provided between the first semiconductor patterns SP1 adjacent to each other in the vertical direction D3. The line patterns 130 may be spaced apart from each other with the first semiconductor patterns SP1 and the buried insulating pattern 110 interposed therebetween. A plurality of line patterns 130 may be provided. The line patterns 130 may be adjacent to the bit line BL and may be provided between the first semiconductor patterns SP1 adjacent to each other in the vertical direction D3.

The line pattern 130 may include an insulating material, and for example, may include at least one of silicon oxide, silicon nitride, silicon oxynitride, or a low-k dielectric material. According to some embodiments, the line pattern 130 may include substantially the same material as the line layer 120.

Hereinafter, various embodiments of the inventive concept will be described with reference to FIGS. 6A and 6B together.

Referring to FIGS. 5A and 6A, a bit line BL may be provided on a second surface side S2 of each of the first semiconductor patterns SP1 that are positioned at a relatively higher level. Accordingly, one bit line BL may contact and be electrically connected to the second surface side S2 of each of the first semiconductor patterns SP1 that are positioned at a relatively higher level and spaced apart from each other in the vertical direction D3.

The line pattern 130 may include a vertical portion 130a extending in the vertical direction D3 and protrusions 130b protruding from the vertical portion 130a. The protrusions 130b may protrude in the first direction D1 from the upper and lower portions of the vertical portion 130a. In contrast, in the case of the line pattern 130 adjacent to the second stacked structure ST2, the protrusions 130b may protrude in a direction opposite to the first direction D1. The protrusions 130b may be spaced apart from each other in the vertical direction D3. The vertical portion 130a may not be in contact with the bit line BL. A portion of the protrusions 130b may extend into the bit line BL. That is, the portion of the protrusions 130b may be in contact with the bit line BL.

An upper insulating pattern 150 may be interposed between the protrusions 130b of the line pattern 130. The upper insulating pattern 150 may be in contact with the vertical portion 130a of the line pattern 130. The vertical portion 130a of the line pattern 130 may be spaced apart from the bit line BL with the upper insulating pattern 150 therebetween. The upper insulating pattern 150 may include an insulating material, and for example, may include at least one of silicon oxide, silicon nitride, silicon oxynitride, or a low-k dielectric material. According to some embodiments, the upper insulating pattern 150 may include substantially the same material as the lower insulating layer 140.

The second edge portion EA2 of the first semiconductor pattern SP1 may extend into the bit line BL. That is, the second surface side S2 of the first semiconductor pattern SP1 may be disposed in the bit line BL.

The first edge portion EA1 of the first semiconductor pattern SP1 may not extend into the data storage pattern DSP. That is, the first edge portion EA1 may not extend into the storage electrode SE.

Referring to FIGS. 5A and 6B, the first edge portion EA1 of the first semiconductor pattern SP1 may extend into the storage electrode SE. That is, the first side surface S1 of the first semiconductor pattern SP1 may be disposed in the storage electrode SE.

Referring again to FIG. 5A, a separation insulating pattern 170 may be provided between the first stacked structure ST1 and the second stacked structure ST2 spaced apart from each other in the first direction D1. The separation insulating pattern 170 may penetrate the lower insulating layer 140. The separation insulating pattern 170 may have a tapered shape toward the substrate 100. The separation insulating pattern 170 may have a V-shape when viewed in a cross-sectional view. A width of the separation insulating pattern 170 in the first direction D1 may change continuously as the separation insulating pattern 170 moves away from the substrate 100 in the vertical direction D3. That is, the width of the separation insulating pattern 170 in the first direction D1 may decrease toward the substrate 100 and may increase from the substrate 100 in the vertical direction D3. A lowermost portion 170b of the separation insulating pattern 170 may be disposed in the lower insulating layer 140.

The separation insulating pattern 170 may include an insulating material, and for example, may include at least one of silicon oxide, silicon nitride, silicon oxynitride, or a low-k dielectric material. According to some embodiments, the separation insulating pattern 170 may include a different material from that of the lower insulating layer 140. The separation insulating pattern 170 may have an etching selectivity with respect to the lower insulating layer 140. For example, when the lower insulating layer 140 includes silicon oxide, the separation insulating pattern 170 may include silicon nitride.

Referring to FIGS. 5A and 7, an upper surface of the lower insulating layer 140 may have a rough structure. The upper surface of the lower insulating layer 140 that vertically overlaps the bit line BL may be disposed at a lower level than uppermost surface 140a of the lower insulating layer 140. The uppermost surfaces 140a of the lower insulating layer 140 may be the upper surfaces disposed at the highest level among the upper surfaces of the lower insulating layer 140 and may be provided on an region that does not vertically overlap the bit line BL. In this specification, the level may mean a distance measured in a vertical direction D3 from a lower surface 100b of the substrate 100.

The uppermost surfaces 140a of the lower insulating layer 140 may be in contact with the first and second line layers 121 and 122, respectively. An upper surface of the lower insulating layer 140 provided on an region vertically overlapping the bit line BL may be referred to as a recessed surface 140R. The recessed surface 140R of the lower insulating layer 140 may be in contact with the bit line BL.

A lower surface of the bit line BL may have a rough structure. The lower surface of the bit line BL vertically overlapping the separation insulating pattern 170 may be disposed at a higher level than the lowermost surfaces BLb of the bit line BL. The lowermost surfaces BLb of the bit line BL may be a surface disposed at the lowermost level among the lower surfaces of the bit line BL and may be provided on an region that does not vertically overlap the separation insulating pattern 170. The recessed surface 140R of the lower insulating layer 140 may be in contact with the lowermost surface BLb of the bit line BL.

The uppermost surface 170a of the separation insulating pattern 170 may be disposed at a higher level than the recessed surface 140R of the lower insulating layer 140. The uppermost surface 170a of the separation insulating pattern 170 may be disposed at a higher level than the lowermost surface BLb of the bit line BL. The uppermost surface 170a of the separation insulating pattern 170 may be disposed at a lower level than the uppermost surface 140a of the lower insulating layer 140. A portion of the separation insulating pattern 170 may extend into the bit line BL. The uppermost surface 170a of the separation insulating pattern 170 may be disposed in the bit line BL.

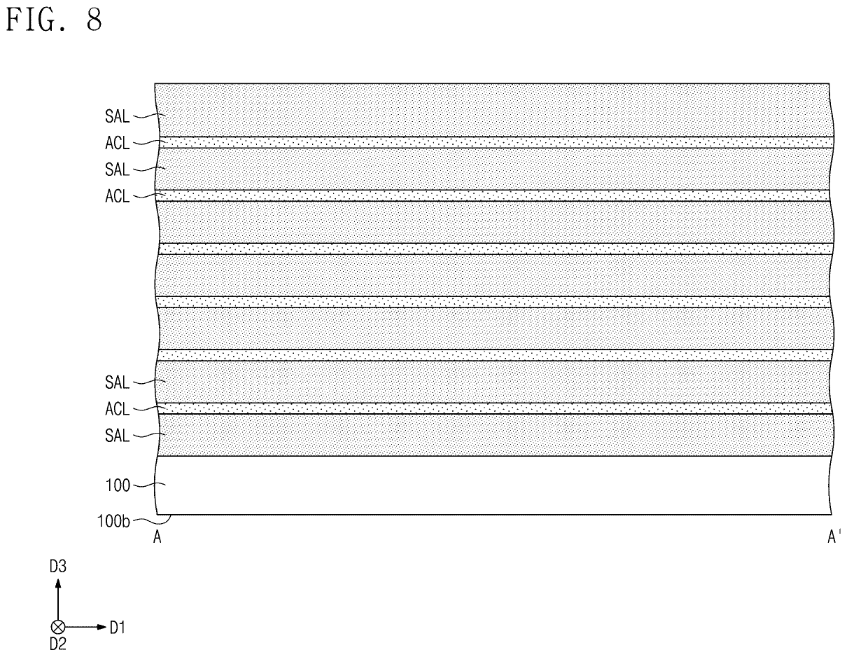

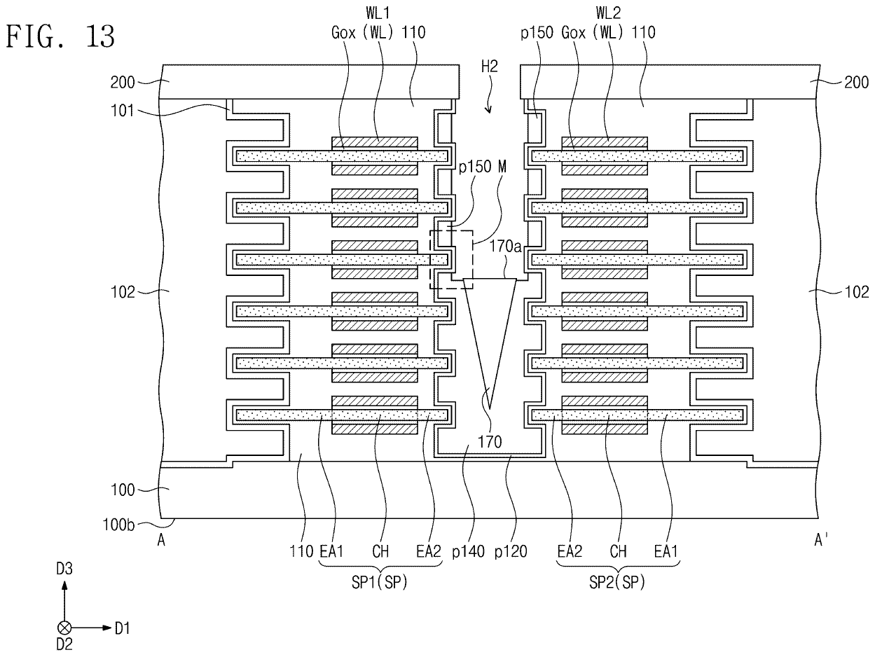

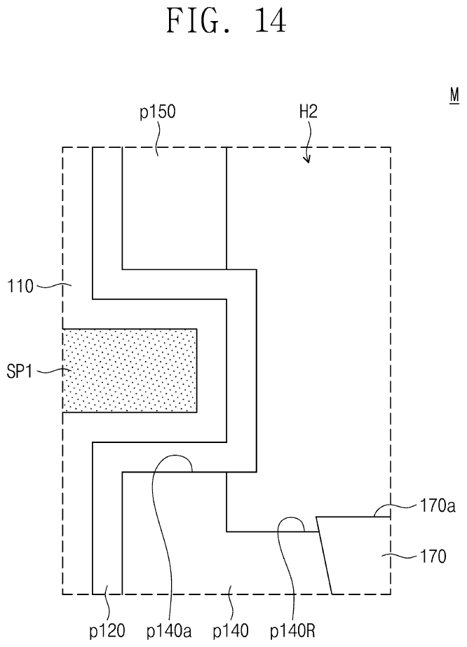

FIGS. 8 to 18 are views illustrating a method of manufacturing a three dimensional semiconductor device according to some embodiments of the inventive concept. In detail, FIGS. 8, 9A, 9B, 9C, 10, 11, 12, 13, 15, and 17 are cross-sectional views corresponding to the line A-A′ of FIG. 4. FIGS. 14, 16, and 18 are enlarged views corresponding to portion ‘M’ of FIGS. 13, 15, and 17, respectively. Hereinafter, a method of manufacturing a three dimensional semiconductor device according to some embodiments of the inventive concept will be described with reference to FIGS. 8 to 18. For simplicity of explanation, explanation of content overlapping the above content will be omitted.

Referring to FIG. 8, sacrificial layers SAL and active layers ACL may be alternately stacked on a substrate 100. Each of the sacrificial layers SAL and the active layers ACL may include a semiconductor material. The sacrificial layers SAL may include a material that has an etching selectivity with respect to the active layers ACL. Accordingly, when the sacrificial layers SAL are removed in a removal process described below, the active layers ACL may not be removed or may be removed to a small extent. For example, the active layers ACL may include one of silicon (Si), germanium (Ge), and silicon-germanium (SiGe), and the sacrificial layers SAL may include one of silicon (Si), germanium (Ge), and silicon-germanium (SiGe) that is different from the active layers ACL. According to some embodiments of the inventive concept, the active layers ACL may include silicon (Si), and the sacrificial layers SAL may include silicon-germanium (SiGe). A thickness of the sacrificial layers SAL may be greater than a thickness of the active layers ACL.

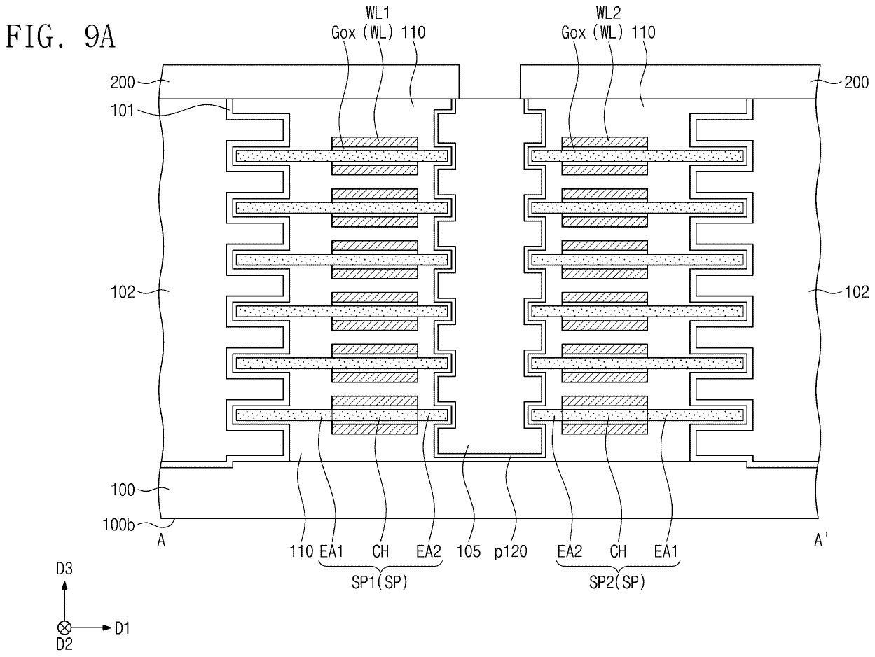

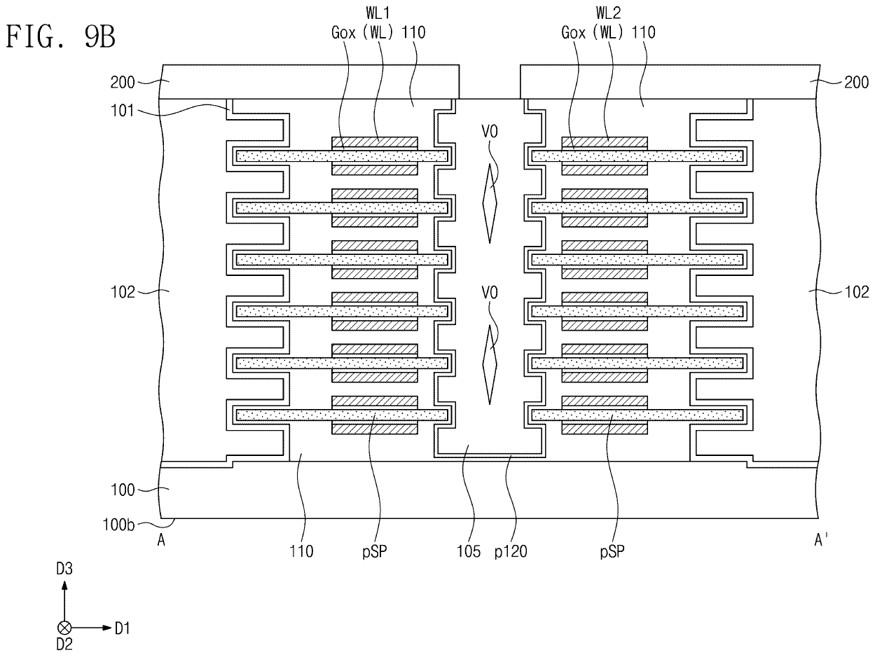

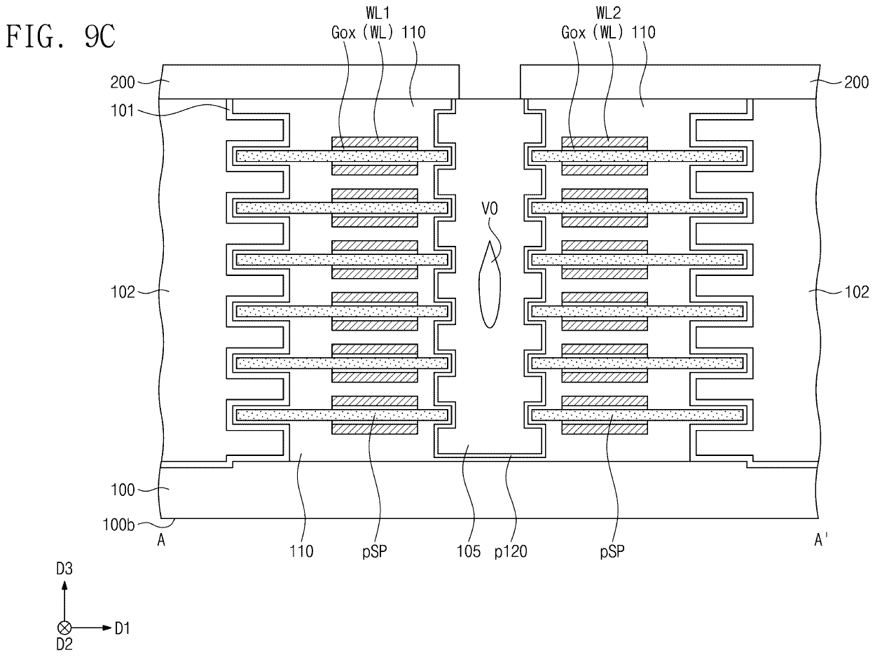

Referring to FIG. 9A, semiconductor patterns SP, gate insulating patterns Gox, word lines WL, buried insulating patterns 110, first sacrificial patterns 101, second sacrificial patterns 102, a preliminary line layer p120, and a preliminary insulating layer 105 may be formed on a substrate 100. Forming the semiconductor patterns SP, the gate insulating patterns Gox, the word lines WL, the buried insulating patterns 110, the first sacrificial patterns 101, the second sacrificial patterns 102, the preliminary line layer p120, and the preliminary insulating layer 105 may be performed by a conventional method. The conventional method may include, for example, forming a plurality of holes (not shown) penetrating the sacrificial layers SAL and the active layers ACL, removing the sacrificial layers SAL exposed by the holes, and forming the above-described components in a space where the sacrificial layers SAL are removed. The described-above order may be changed as needed. That is, forming a plurality of holes (not shown), removing the sacrificial layers SAL, and forming the above-described components may be performed by a person skilled in the art by combining various orders as needed, and the inventive concept is not limited thereto.

The preliminary insulating layer 105 may be interposed between the first semiconductor patterns SP1 and the second semiconductor patterns SP2 spaced apart from each other in the first direction D1. The preliminary insulating layer 105 may extend in the vertical direction D3. The preliminary line layer p120 may be interposed between the preliminary insulating layer 105 and the buried insulating pattern 110. The preliminary insulating layer 105 may be spaced apart from the buried insulating pattern 110 with the preliminary line layer p120 interposed therebetween.

The preliminary insulating layer 105 and the preliminary line layer p120 may include an insulating material, and for example, may include at least one of silicon oxide, silicon nitride, silicon oxynitride, or a low-k dielectric material. According to some embodiments, the preliminary insulating layer 105 and the preliminary line layer p120 may include different materials. The preliminary insulating layer 105 and the preliminary line layer p120 may have an etching selectivity. For example, when the preliminary insulating layer 105 includes silicon oxide, the preliminary line layer p120 may include silicon nitride.

The first and second sacrificial patterns 101 and 102 may be disposed adjacent to the first edge portions EA1 of each of the first semiconductor patterns SP1. The first sacrificial pattern 101 may be interposed between the buried insulating pattern 110 and the second sacrificial pattern 102. In addition, the first and second sacrificial patterns 101 and 102 may be disposed adjacent to the first edge portions EA1 of each of the second semiconductor patterns SP2.

Subsequently, an upper insulating layer 200 may be formed on the first and second sacrificial patterns 101 and 102, the buried insulating pattern 110, and the preliminary line layer p120. The upper insulating layer 200 may expose an upper surface of the preliminary insulating layer 105.

Referring to FIGS. 9B and 9C, a void VO may be formed in the preliminary insulating layer 105 during the process of forming the preliminary insulating layer 105. A plurality of voids VO may be formed. For example, as shown in FIG. 9B, diamond-shaped voids VO may be formed. The voids VO may be formed spaced apart from each other in the vertical direction D3. As another example, as shown in FIG. 9C, water drop-shaped voids VO may be formed. The number and shape of the voids VO may be formed in various ways, and the inventive concept is not limited thereto.

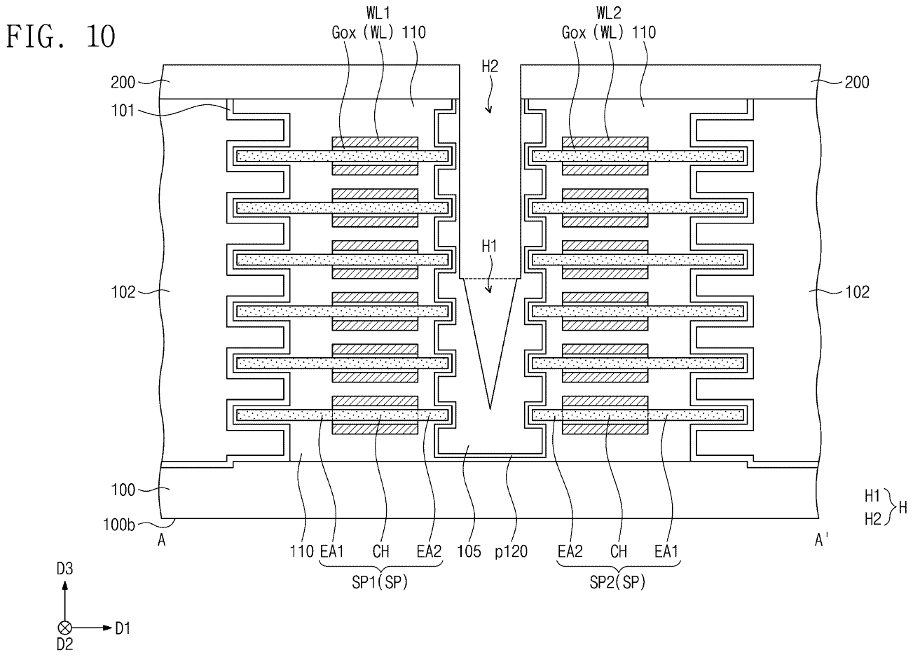

Referring to FIG. 10, a portion of a preliminary insulating layer 105 may be etched to form a hole H. The hole H may include a first region H1 and a second region H2. The hole H may be formed by performing an etching process on the preliminary insulating layer 105.

The first region H1 of the hole H may be interposed between the first group of the first semiconductor patterns SP1 and the first group of the second semiconductor patterns SP2. The first region H1 of the hole H may horizontally overlap the first group of the first semiconductor patterns SP1 and the first group of the second semiconductor patterns SP2. Specifically, the first region H1 of the hole H may be disposed adjacent to the first and second semiconductor patterns SP1 and SP2 which are positioned relatively lower among the first and second semiconductor patterns SP1 and SP2 spaced apart from each other in the vertical direction D3. The first region H1 of the hole H may have a V-shape. A width of the first region H1 of the hole H in the first direction D1 may continuously change from the substrate 100 in the vertical direction D3. That is, the width of the first region H1 of the hole H in the first direction D1 may increase from the substrate 100 in the vertical direction D3. According to some embodiments, the first region H1 of the hole H may not penetrate the preliminary line layer p120. That is, the first region H1 of the hole H may be disposed in the preliminary insulating layer 105.

The second region H2 of the hole H may be interposed between the second group of the first semiconductor patterns SP1 and the second group of the second semiconductor patterns SP2. The second region H2 of the hole H may horizontally overlap the second group of the first semiconductor patterns SP1 and the second group of the second semiconductor patterns SP2. Specifically, the second region H2 of the hole H may be disposed adjacent to the first and second semiconductor patterns SP1 and SP2 that are relatively disposed upper among the first and second semiconductor patterns SP1 and SP2 spaced apart from each other in the vertical direction D3. A width of the second region H2 of the hole H in the first direction D1 may be constant. That is, the width of the second region H2 of the hole H in the first direction D1 may not change even when moving away from the substrate 100 in the vertical direction D3. The width of the second region H2 in the first direction D1 may be larger than the width of the first region H1 in the first direction D1.

According to the inventive concept, the hole H having the above-described shape may be due to the voids VO described with reference to FIGS. 9B and 9C. That is, a region where the voids VO are formed may be exposed during the process of etching the preliminary insulating layer 105 and may be relatively more vulnerable to the etching process. Accordingly, the first region H1 of the hole H may have a V-shape.

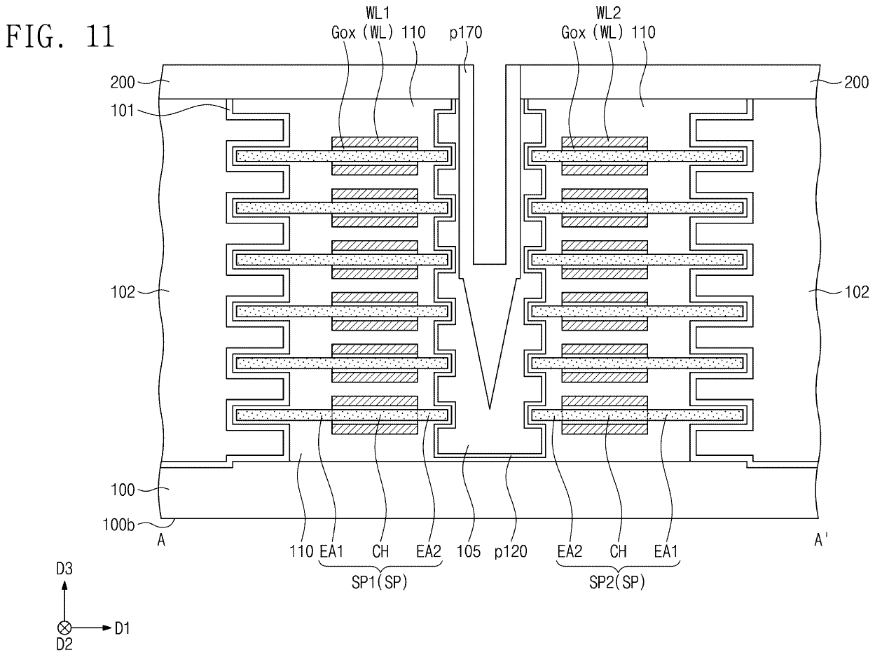

Referring to FIG. 11, a separation insulating layer p170 filling a hole H may be formed. The separation insulating layer p170 may fill the first region H1 of the hole H. However, the separation insulating layer p170 may not completely fill the second region H2 of the hole H. That is, the separation insulating layer p170 may be formed to cover a side wall of the second region H2.

The separation insulating layer p170 may include an insulating material, and for example, may include at least one of silicon oxide, silicon nitride, silicon oxynitride, or a low-k material. According to some embodiments, the separation insulating layer p170 may include a different material from that of the preliminary insulating layer 105. The separation insulating layer p170 and the preliminary insulating layer 105 may have an etching selectivity. For example, when the preliminary insulating layer 105 includes silicon oxide, the separation insulating layer p170 may include silicon nitride.

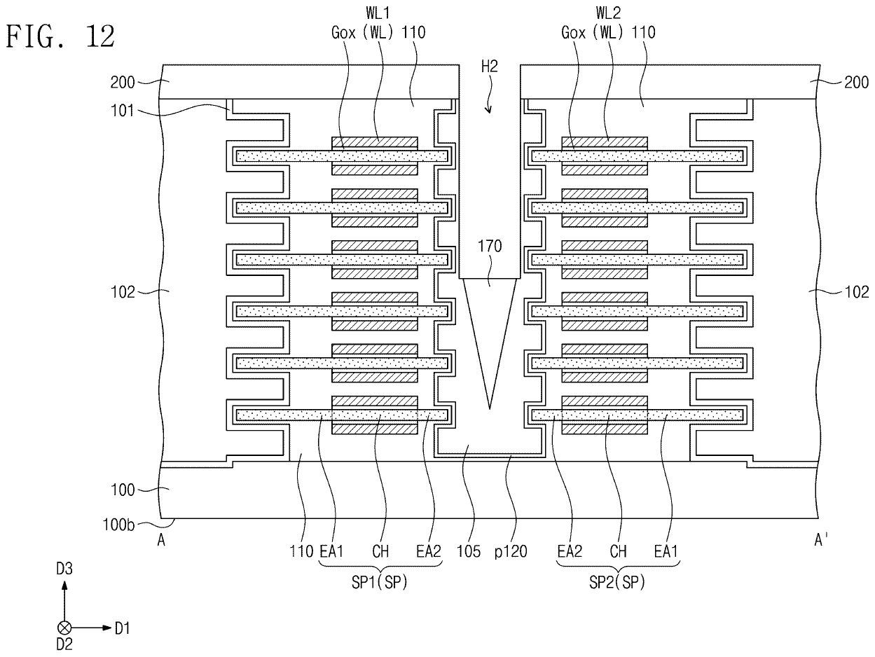

Referring to FIG. 12, the second region H2 of the hole H may be exposed again. Re-exposing the second region H2 may be performed, for example, through an etching process for the separation insulating layer p170. By the etching process for the separation insulating layer p170, the separation insulating pattern 170 may be formed.

Referring to FIGS. 13 and 14, the preliminary insulating layer 105 may be separated into a preliminary lower insulating layer p140 and preliminary upper insulating patterns p150. The preliminary lower insulating layer p140 and the preliminary upper insulating patterns p150 may be formed, for example, through a first etching process for the preliminary insulating layer 105. During the first etching process, the preliminary line layer p120 may not be etched. Accordingly, a side surface of the preliminary line layer p120 that horizontally overlaps the second region H2 may be exposed by the etching process.

An upper surface of the preliminary lower insulating layer p140 may have an uneven structure. The uppermost surfaces p140a of the preliminary lower insulating layer p140 may be a top at the highest level among the upper surfaces of the preliminary lower insulating layer p140. A recessed surface p140R of the preliminary lower insulating layer p140 may be an upper surface of a region vertically overlapping the second region H2. During the first etching process, the separation insulating pattern 170 may not be etched. Accordingly, the recessed surface p140R of the preliminary lower insulating layer p140 may be disposed at a lower level than the uppermost surface 170a of the separation insulating pattern 170. The uppermost surfaces p140a of the preliminary lower insulating layer p140 may be disposed at a higher level than the uppermost surface 170a of the separation insulating pattern 170.

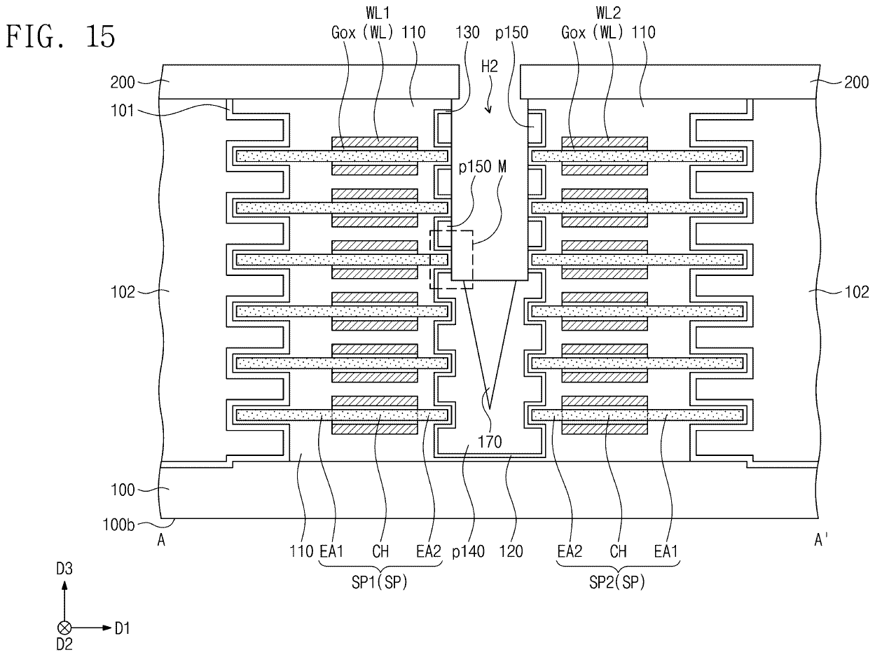

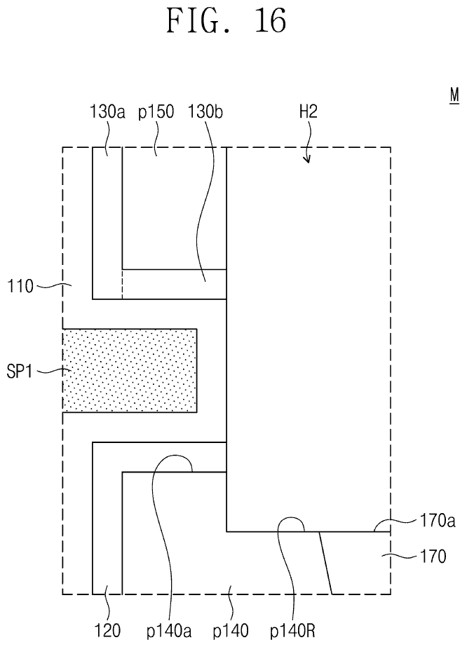

Referring to FIGS. 15 and 16, the preliminary line layer p120 may be separated into a line layer 120 and line patterns 130. The line layer 120 and the line patterns 130 may be formed, for example, through a strip process on the preliminary line layer p120. A side surface of the preliminary line layer p120 exposed by the first etching process among the preliminary line layers p120 may be removed through the strip process. Accordingly, the preliminary line layer p120 may be separated into the line layer 120 and the line patterns 130. While the strip process is performed, the preliminary upper insulating patterns p150 may not be etched. Each of the line patterns 130 may be disposed between the semiconductor patterns SP adjacent to each other in the vertical direction D3. Each of the line patterns 130 may not horizontally overlap the semiconductor patterns SP.

Each of the line patterns 130 may include a vertical portion 130a extending in the vertical direction D3 and protrusions 130b protruding from the vertical portion 130a. A portion of the side surface of the buried insulating pattern 110 may be exposed between the line patterns 130 adjacent to each other in the vertical direction D3. Specifically, a portion of the side surface of the buried insulating pattern 110 may be exposed between the protrusions 130b of each of the line patterns 130 adjacent to each other in the vertical direction D3. In addition, a portion of the side surface of the buried insulating pattern 110 may be exposed between the protrusion 130b of the lowermost line pattern 130 among the line patterns 130 and the uppermost portion of the line layer 120.

While the strip process is performed, the preliminary lower insulating layer p140 may not be etched. During the strip process, a portion of the separation insulating pattern 170 may be etched. The uppermost surface 170a of the separation insulating pattern 170 may be disposed at a lower level than the uppermost surfaces p140a of the preliminary lower insulating layer p140. According to some embodiments, the uppermost surface 170a of the separation insulating pattern 170 may be disposed at substantially the same level as the recessed surface p140R of the preliminary lower insulating layer p140. According to another embodiment, although not illustrated, the uppermost surface 170a of the separation insulating pattern 170 may be disposed at a lower level than the recessed surface p140R of the preliminary lower insulating layer p140. According to yet another embodiment, although not illustrated, the uppermost surface 170a of the separation insulating pattern 170 may be disposed at a higher level than the recessed surface p140R of the preliminary lower insulating layer p140. However, the inventive concept is not limited thereto.

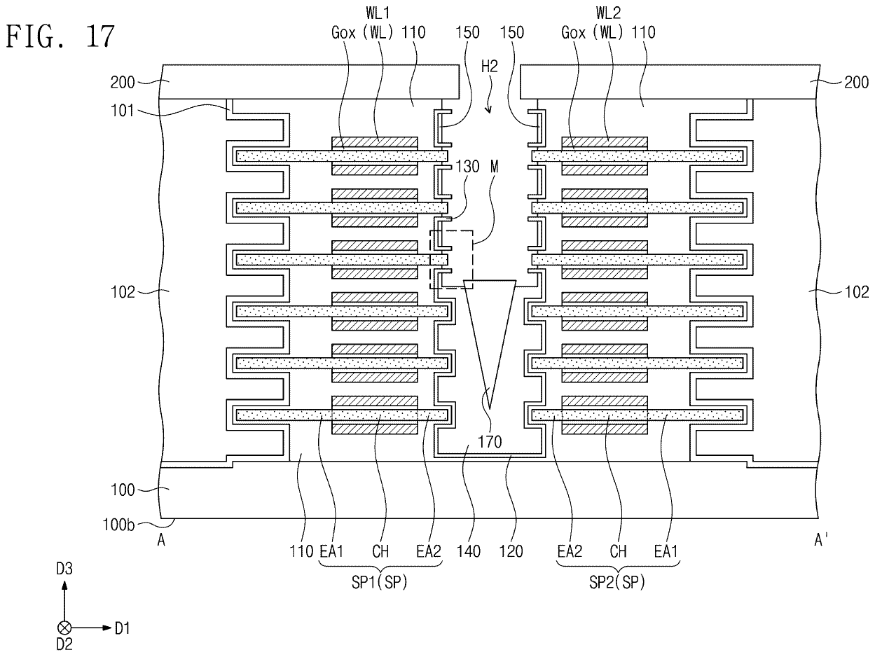

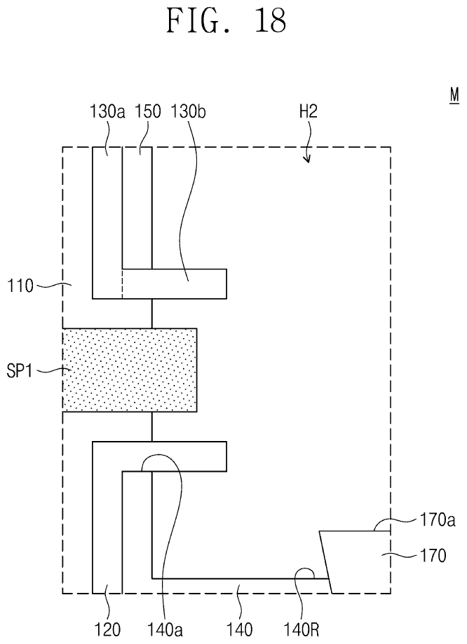

Referring to FIGS. 17 and 18, upper insulating patterns 150 may be formed between line patterns 130 adjacent to each other in the vertical direction D3. The upper insulating patterns 150 may be formed, for example, by a second etching process for the preliminary upper insulating patterns p150. While the second etching process is performed, the line patterns 130 may not be etched. Accordingly, portions of the protrusions 130b of each of the line patterns 130 may be exposed.

While the second etching process is performed, a portion of side surfaces of the exposed buried insulating pattern 110 may be etched. Accordingly, side surfaces of the semiconductor patterns SP that horizontally overlap the second region H2 may be exposed. Specifically, a portion of the second edge portion EA2 of each of the semiconductor patterns SP that horizontally overlap the second region H2 may be exposed. A portion of the exposed second edge portion EA2 may be disposed between the line patterns 130 that are adjacent to each other in the vertical direction D3. In addition, while the second etching process is performed, the line layer 120 may not be etched. Accordingly, a portion of the second edge portion EA2 of each of the semiconductor patterns SP that is disposed between the protrusion 130b of the line pattern 130 at the lowermost position among the line patterns 130 and the uppermost portion of the line layer 120 may be exposed.

By the second etching process, a portion of the preliminary lower insulating layer p140 may be etched to form the lower insulating layer 140. Specifically, a portion of the preliminary lower insulating layer p140 exposed by the second region H2 may be etched. During the second etching process, the separation insulating pattern 170 may not be etched. Accordingly, the recessed surface 140R of the lower insulating layer 140 may be formed at a lower level than the uppermost surface 170a of the separation insulating pattern 170.

Referring again to FIGS. 5A and 5B, a bit line BL filling the second region H2 may be formed. Subsequently, after the first and second sacrificial patterns 101 and 102 are removed, a data storage pattern DSP may be formed. The bit line BL and the data storage pattern DSP may be formed using a layer-forming technique such as chemical vapor deposition (CVD), physical vapor deposition (PVD), atomic layer deposition (ALD), etc. The bit line BL and the data storage pattern DSP may be formed through a conventional method, and the inventive concept is not limited thereto.

According to the inventive concept, the bit line BL may be clearly isolated from the substrate 100. The separation insulating pattern 170 may be additionally disposed below the bit line BL to prevent a bridge defect between the bit line BL and the substrate 100. The lower insulating layer 140 and the separation insulating pattern 170 may have an etching selectivity. The lower insulating layer 140 that is not exposed by the separation insulating pattern 170 may not be etched during the first and second etching processes. Accordingly, the bit line BL may be clearly isolated from the substrate 100, and a three dimensional semiconductor device with improved electrical characteristics and reliability may be provided.

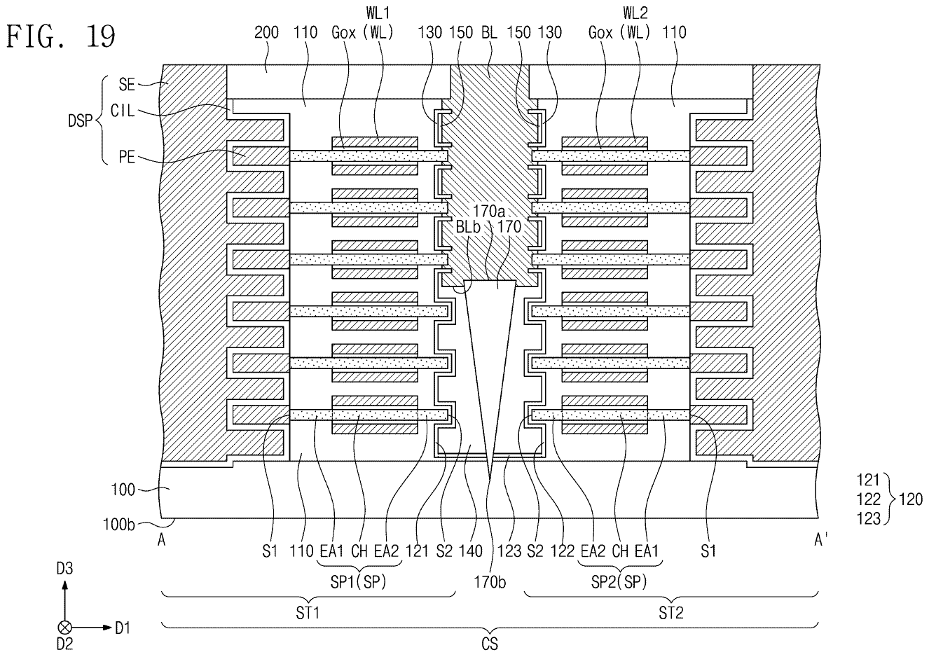

FIGS. 19 to 21 are drawings illustrating a three dimensional semiconductor device according to some embodiments of the inventive concept, and are cross-sectional views corresponding to the line A-A′ of FIG. 4. To simplify the explanation, overlapping content with the above description will be omitted, and differences will be mainly described.

Referring to FIG. 19, the separation insulating pattern 170 may be provided to extend toward the substrate 100. That is, the separation insulating pattern 170 may extend in a direction opposite to the vertical direction D3. The separation insulating pattern 170 may penetrate the horizontal line layer 120 and the buried insulating pattern 110, and may penetrate a portion of the substrate 100. The lowermost portion 170b of the separation insulating pattern 170 may be disposed in the substrate 100.

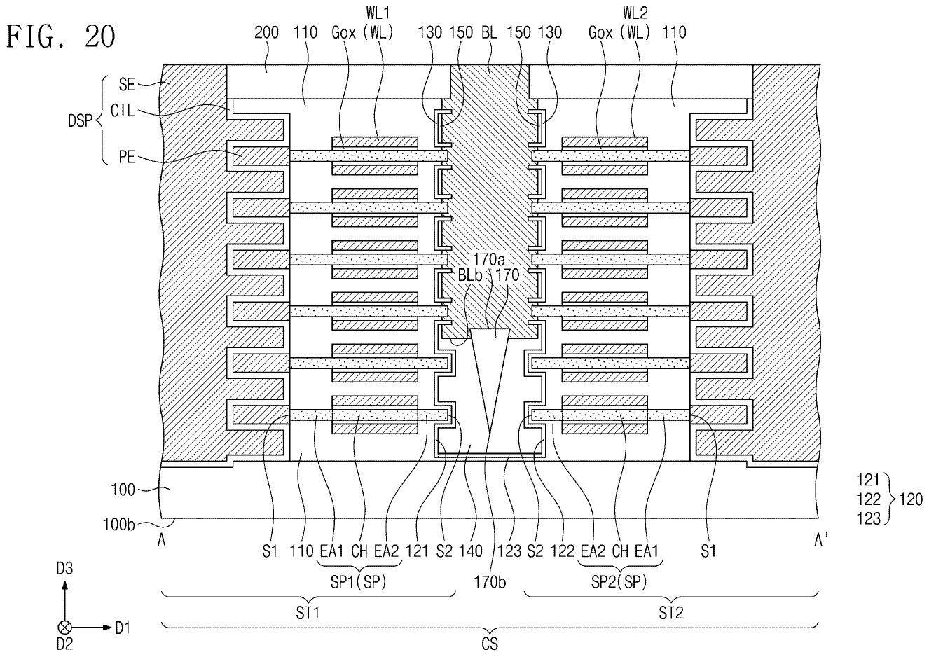

Referring to FIG. 20, the lowermost surface BLb of the bit line BL may be disposed at a relatively lower level compared to FIG. 5A. That is, only the two lowermost layers of semiconductor patterns SP among the semiconductor patterns SP may not be connected to the bit line BL. Accordingly, a relatively larger number of semiconductor patterns SP may be connected to the bit line BL compared to FIG. 5A, and a relatively larger number of memory cells may be configured.

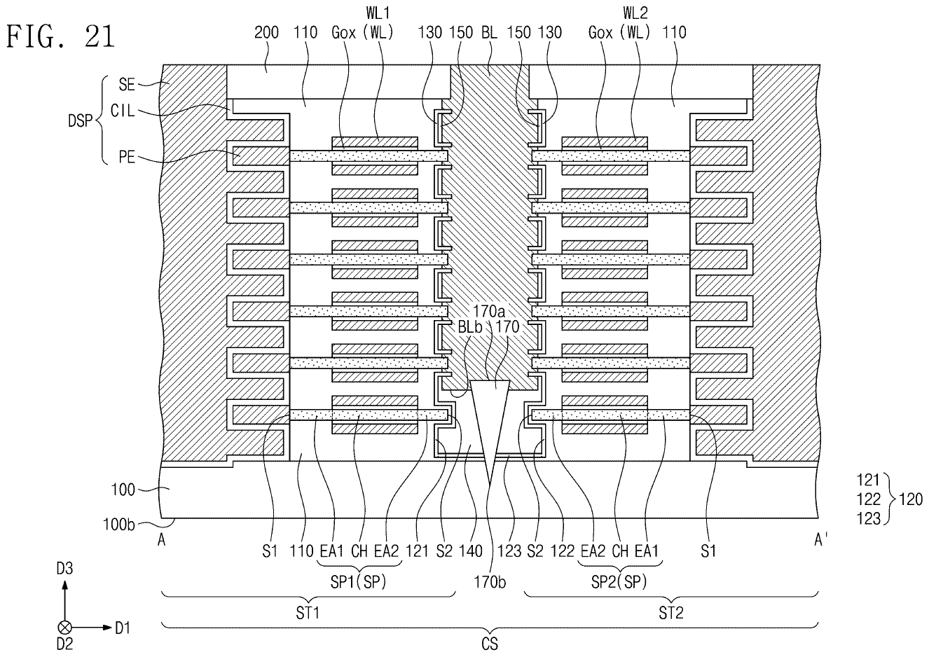

Referring to FIG. 21, the separation insulating pattern 170 may be provided to extend toward the substrate 100. The separation insulating pattern 170 may penetrate the horizontal line layer 120 and the buried insulating pattern 110, and may penetrate a portion of the substrate 100. The lowermost portion 170b of the separation insulating pattern 170 may be disposed in the substrate 100. In addition, the lowermost surface BLb of the bit line BL may be disposed at a relatively lower level compared to FIG. 5A. That is, only the lowermost semiconductor patterns SP among the semiconductor patterns SP may not be connected to the bit line BL. Accordingly, a relatively larger number of semiconductor patterns SP may be connected to the bit line BL compared to FIG. 5A, and a relatively larger number of memory cells may be configured.

According to the inventive concept, the bit line may be clearly isolated from the substrate. The separation insulating pattern is additionally disposed below the bit line to prevent the bridge failure between the bit line and the substrate. The lower insulating layer and the separation insulating pattern may have an etching selectivity. The lower insulating layer that is not exposed by the separation insulating pattern may not be etched while the etching process for the lower insulating layer with the same material is performed. Accordingly, the bit line may be clearly isolated from the substrate, and the three dimensional semiconductor device with improved electrical characteristics and reliability may be provided.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A three dimensional semiconductor device comprising:
semiconductor patterns disposed on a substrate, extending in a first direction parallel to a lower surface of the substrate, spaced apart from each other in a vertical direction perpendicular to the lower surface of the substrate;
word lines respectively surrounding the semiconductor patterns, extending in a second direction parallel to the lower surface of the substrate and orthogonal to the first direction;
a lower insulating layer disposed adjacent to ends of a first group of the semiconductor patterns;
a bit line disposed on the lower insulating layer and adjacent to ends of a second group of the semiconductor patterns; and
a separation insulating pattern penetrating at least a portion of the lower insulating layer,
wherein the separation insulating pattern has a shape tapered toward the substrate.

2. The three dimensional semiconductor device of claim 1, wherein the lower insulating layer and the separation insulating pattern include different materials.

3. The three dimensional semiconductor device of claim 1, wherein an uppermost surface of the separation insulating pattern is disposed at a level higher than a recessed surface of the lower insulating layer.

4. The three dimensional semiconductor device of claim 1, wherein an uppermost surface of the separation insulating pattern is disposed at a higher level than a lowermost surface of the bit line.

5. The three dimensional semiconductor device of claim 1, wherein at least one of the first group of the semiconductor patterns are disposed at a lower level than a lowermost surface of the bit line.

6. The three dimensional semiconductor device of claim 1, wherein a lowermost portion of the separation insulating pattern is disposed in the lower insulating layer.

7. The three dimensional semiconductor device of claim 1, wherein a lowermost portion of the separation insulating pattern is disposed in the substrate.

8. The three dimensional semiconductor device of claim 1, wherein a width of the separation insulating pattern in the first direction increases in a direction away from the substrate in the vertical direction.

9. A three dimensional semiconductor device comprising:
semiconductor patterns disposed on a substrate, extending in a first direction parallel to a lower surface of the substrate, spaced apart from each other in a vertical direction perpendicular to the lower surface of the substrate;
word lines respectively surrounding the semiconductor patterns, extending in a second direction parallel to the lower surface of the substrate and orthogonal to the first direction;
a lower insulating layer disposed adjacent to end portions of a first group the semiconductor patterns;
a bit line disposed on the lower insulating layer and adjacent to end portions of a second group of the semiconductor patterns; and
a separation insulating pattern penetrating at least a portion of the lower insulating layer,
wherein an uppermost surface of the separation insulating pattern is disposed at a higher level than a recessed surface of the lower insulating layer.

10. The three dimensional semiconductor device of claim 9, wherein the lower insulating layer and the separation insulating pattern include different materials.

11. The three dimensional semiconductor device of claim 9, the separation insulating pattern has a V-shape when viewed in a cross-sectional view.

12. The three dimensional semiconductor device of claim 9, wherein a width of the separation insulating pattern in the first direction increases in a direction away from the substrate in the vertical direction.

13. The three dimensional semiconductor device of claim 9, wherein the uppermost surface of the separation insulating pattern is disposed at a level higher than a lowermost surface of the bit line.

14. The three dimensional semiconductor device of claim 9, wherein at least one of the first group of the semiconductor patterns are disposed at a level lower than a lowermost surface of the bit line.

15. The three dimensional semiconductor device of claim 9, wherein a lowermost portion of the separation insulating pattern is disposed in the substrate.

16. A three dimensional semiconductor device comprising:
semiconductor patterns disposed on a substrate, extending in a first direction parallel to a lower surface of the substrate, spaced apart from each other in a vertical direction perpendicular to the lower surface of the substrate, each of the semiconductor patterns having a first end and a second end opposing each other in the first direction;
word lines respectively surrounding the semiconductor patterns, extending in a second direction parallel to the lower surface of the substrate and orthogonal to the first direction;
gate insulating patterns disposed between the semiconductor patterns and the word lines, respectively;
data storage patterns connected to the first ends of the semiconductor patterns, extending in the vertical direction;
a lower insulating layer disposed adjacent to the second ends of a first group of the semiconductor patterns;
a bit line disposed on the lower insulating layer and adjacent to the second ends of a second group of the semiconductor patterns; and
a separation insulating pattern penetrating at least a portion of the lower insulating layer,
wherein a width of the separation insulating pattern in the first direction continuously changes in the vertical direction.

17. The three dimensional semiconductor device of claim 16, wherein the lower insulating layer and the separation insulating pattern include different materials.

18. The three dimensional semiconductor device of claim 16, wherein an uppermost surface of the separation insulating pattern is disposed at a level higher than a recessed surface of the lower insulating layer.

19. The three dimensional semiconductor device of claim 16, wherein at least one of the first group of the semiconductor patterns is disposed at a level lower than a lowermost surface of the bit line.

20. The three dimensional semiconductor device of claim 16, wherein a lowermost portion of the separation insulating pattern is disposed in the substrate.
